(19) United States
(12) Patent Application Publication
(10) Pub. No.: US 2024/0241997 A1
(43) Pub. Date: Jul. 18, 2024

(54) SYSTEM AND METHOD FOR CLASSIFYING B-REP-BASED CAD MODELS

(71) Applicant: HCL Technologies Limited, New Delhi (IN)

(72) Inventors: Hari Krishnan Elumalai, Chennai (IN); Akash Agrawal, Pune (IN); Pankaj Panda, Navi Mumbai (IN); Rajesh Chakravarty, Navi Mumbai (IN)

(21) Appl. No.: 18/225,705

(22) Filed: Jul. 25, 2023

(30) Foreign Application Priority Data
Jan. 13, 2023 (IN) 202311002715

(51) Int. Cl. G06F 30/12

(52) U.S. Cl. CPC G06F 30/12

(57) ABSTRACT

The invention relates to method and system for classifying Boundary Representation (B-Rep)-based Computer Aided Design (CAD) models. The method includes extracting information corresponding to an input B-Rep-based CAD model; and determining a model type associated with the B-Rep-based CAD model from a set of model types based on the information. The set of model types includes valid model types and invalid model types. When the determined model type is one of the valid model types, the method may further include validating the B-Rep-based CAD model based on a set of user input parameters; upon successful validation, analysing, each of the set of faces of the B-Rep-based CAD model based on a reference face selected from the set of faces using a heuristic model; and labelling the B-Rep-based CAD model as one of a sheet metal body, a non-sheet metal body, or an unclassified body based on the analysis.

### TECHNICAL FIELD

Generally, the invention relates to Boundary Representation (B-Rep) models. More specifically, the invention relates to a system and method for classifying Boundary Representation (B-Rep)-based Computer Aided Design (CAD) models.

### BACKGROUND

Typically, a Boundary representation (B-Rep) model of a mechanical part includes faces, edges, and vertices. The faces, the edges, and the vertices may be connected to form a topological structure of the mechanical part. Information of the B-Rep model of the mechanical part may be stored in a graph structure. In the graph structure, each node represents a face, and each link/connection represents an edge. This type of representation helps in evaluating properties of the mechanical part. The properties may include mass, volume, moment of inertia, and the like. Additionally, such B-Rep models enable computer-based analysis of stress and strains in the mechanical part under different loading conditions. Further, a B-Rep-based computer model may also be cut and examined in a manner like an actual part. Therefore, the B-Rep model of the mechanical part is known as a solid model.

Today, various software based on solid modeling are widely used by engineers to create models of the mechanical parts that are intended to eventually be manufactured. Examples of the software may include SolidWorks® and Catia (Dassault Systems), Creo Parametric (PTC), and the like.

Sheet metal models are created by sheet metal operations like blanking, bending, punching, etc. Sheet metal models are typically characterized by uniform thickness throughout. These models mainly include elements such as, walls, bends, form, and stamp elements. Non-sheet metal models are created by operations other than sheet metal operations such as, turning, milling, injection moulding, etc.

Further, various techniques for classifying the B-Rep-based CAD models are available. However, the existing techniques lack in classifying the B-Rep-based CAD models as sheet metal models, non-sheet metal models, or unclassified bodies along with providing information of such unclassified bodies to the user. Further, the existing techniques fail in classifying the bodies as sheet metal bodies when thickness value of the bodies is changed from a typical thickness value. There is, therefore, a need in the present state of art for techniques for classification of B-Rep-based CAD models into sheet metal and non-sheet metal bodies.

### SUMMARY

In one embodiment, a method for classifying Boundary Representation (B-Rep)-based Computer Aided Design (CAD) models is disclosed. The method may include extracting information corresponding to an input B-Rep-based CAD model. The B-Rep-based CAD model may include a set of faces, and the information may include a plurality of features associated with the B-Rep-based CAD model. The method may further include determining a model type associated with the B-Rep-based CAD model from a set of model types based on the information. The set of model types may include valid model types and invalid model types, and the invalid model types may include a non-manifold body, a multi-part body, a surface body, a wire body, and a free-form region. The surface body and the wire body may be processed further to identify tap bodies. When the determined model type is one of the valid model types, the method may further include validating the B-Rep-based CAD model based on a set of user input parameters. The set of user input parameters may include a maximum thickness value and a minimum aspect ratio. The method may further include, upon successful validation, analysing each of the set of faces of the B-Rep-based CAD model based on a reference face selected from the set of faces using a heuristic model. The method may further include labelling the B-Rep-based CAD model as one of a sheet metal body, a non-sheet metal body, or an unclassified body based on the analysis.

In another embodiment, a system for classifying Boundary Representation (B-Rep)-based Computer Aided Design (CAD) models is disclosed. The system may include a processor and a memory communicatively coupled to the processor. The memory may store processor-executable instructions, which on execution, may further cause the processor to extract information corresponding to an input B-Rep-based CAD model. The B-Rep-based CAD model may include a set of faces and the information may include a plurality of features associated with the B-Rep-based CAD model. The processor-executable instructions, on execution, may further cause the processor to determine a model type associated with the B-Rep-based CAD model from a set of model types based on the information. The set of model types may include valid model types and invalid model types, and the invalid model types may include a non-manifold body, a multi-part body, a surface body, a wire body, and a free-form region. The surface body and the wire body may be processed further to identify tap bodies. When the determined model type is one of the valid model types, the processor-executable instructions, on execution, may further cause the processor to validate the B-Rep-based CAD model based on a set of user input parameters. The set of user input parameters may include a maximum thickness value and a minimum aspect ratio. The processor-executable instructions, on execution, may further cause the processor to analyze each of the set of faces of the B-Rep-based CAD model based on a reference face selected from the set of faces using a heuristic model, upon successful validation. The processor-executable instructions, on execution, may further cause the processor to label the B-Rep-based CAD model as one of a sheet metal body, a non-sheet metal body, or an unclassified body based on the analysis.

In yet another embodiment, a non-transitory computer-readable medium storing computer-executable instructions for classifying Boundary Representation (B-Rep)-based Computer Aided Design (CAD) models is disclosed. The stored instructions, when executed by a processor, may cause the processor to perform operations including extracting information corresponding to an input B-Rep-based CAD model. The B-Rep-based CAD model may include a set of faces, and the information may include a plurality of features associated with the B-Rep-based CAD model. The operations may further include determining a model type associated with the B-Rep-based CAD model from a set of model types based on the information. The set of model types may include valid model types and invalid model types, and the invalid model types may include a non-manifold body, a multi-part body, a surface body, a wire body, and a free-form region. The surface body and the wire body may be processed further to identify tap bodies. When the determined model type is one of the valid model types, the operations may further include validating the B-Rep-based CAD model based on a set of user input parameters. The set of user input parameters may include a maximum thickness value and a minimum aspect ratio. The operations may further include, upon successful validation, analysing each of the set of faces of the B-Rep-based CAD model based on a reference face selected from the set of faces using a heuristic model. The operations may further include labelling the B-Rep-based CAD model as one of a sheet metal body, a non-sheet metal body, or an unclassified body based on the analysis.

It is to be understood that both the foregoing general description and the following detailed description are exemplary and explanatory only and are not restrictive of the invention, as claimed.

### BRIEF DESCRIPTION OF THE DRAWINGS

The present application can be best understood by reference to the following description taken in conjunction with the accompanying drawing figures, in which like parts may be referred to by like numerals

FIG. 1 illustrates a block diagram of a system for classifying Boundary Representation (B-Rep)-based Computer Aided Design (CAD) models, in accordance with some embodiments of the present disclosure.

FIG. 2 illustrates a flow diagram of an exemplary process for classifying Boundary Representation (B-Rep)-based Computer Aided Design (CAD) models, in accordance with some embodiments of the present disclosure.

FIG. 3 illustrates a flow diagram of an exemplary process for identifying tap bodies, in accordance with some embodiments of the present disclosure.

FIG. 4 illustrates an exemplary sheet metal body with segregated faces, in accordance with some embodiments of the present disclosure.

FIG. 5 illustrates exemplary sheet metal fasteners, in accordance with some embodiments of the present disclosure.

FIG. 6 illustrates exemplary sheet metal markings, in accordance with some embodiments of the present disclosure.

FIG. 7 illustrates exemplary sheet metal half shears, in accordance with some embodiments of the present disclosure.

FIG. 8 illustrates exemplary sheet metal chamfers, in accordance with some embodiments of the present disclosure.

FIG. 9 illustrates exemplary bevels in a sheet metal body, in accordance with some embodiments of the present disclosure.

FIG. 10 illustrates exemplary Boundary Representation (B-Rep)-based Computer Aided Design (CAD) models, in accordance with some embodiments of the present disclosure.

FIG. 11 is a block diagram of an exemplary computer system for implementing embodiments consistent with the present disclosure.

### DETAILED DESCRIPTION OF THE DRAWINGS

The following description is presented to enable a person of ordinary skill in the art to make and use the invention and is provided in the context of particular applications and their requirements. Various modifications to the embodiments will be readily apparent to those skilled in the art, and the generic principles defined herein may be applied to other embodiments and applications without departing from the spirit and scope of the invention. Moreover, in the following description, numerous details are set forth for the purpose of explanation. However, one of ordinary skill in the art will realize that the invention might be practiced without the use of these specific details. In other instances, well-known structures and devices are shown in block diagram form in order not to obscure the description of the invention with unnecessary detail. Thus, the present invention is not intended to be limited to the embodiments shown, but is to be accorded the widest scope consistent with the principles and features disclosed herein.

While the invention is described in terms of particular examples and illustrative figures, those of ordinary skill in the art will recognize that the invention is not limited to the examples or figures described. Those skilled in the art will recognize that the operations of the various embodiments may be implemented using hardware, software, firmware, or combinations thereof, as appropriate. For example, some processes can be carried out using processors or other digital circuitry under the control of software, firmware, or hard-wired logic. (The term “logic” herein refers to fixed hardware, programmable logic and/or an appropriate combination thereof, as would be recognized by one skilled in the art to carry out the recited functions). Software and firmware can be stored on computer-readable storage media. Some other processes can be implemented using analog circuitry, as is well known to one of ordinary skill in the art. Additionally, memory or other storage, as well as communication components, may be employed in embodiments of the invention.

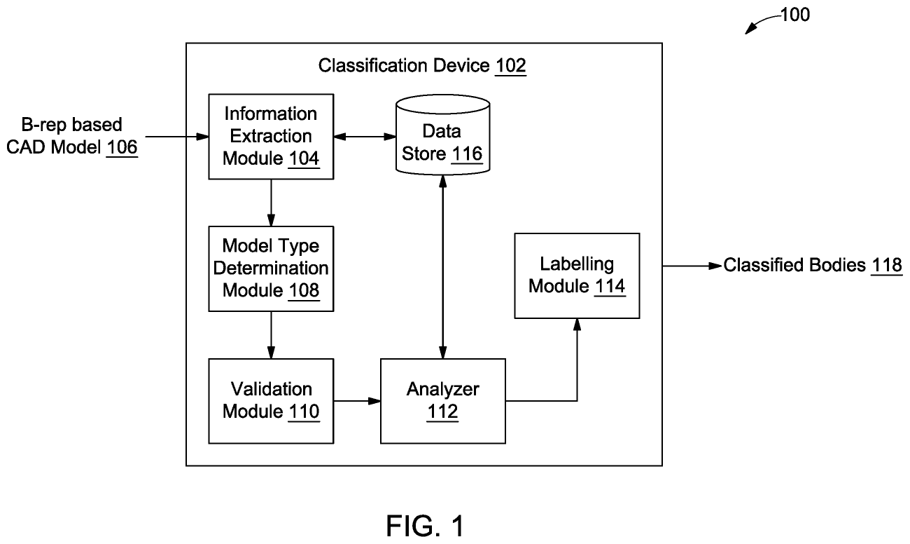

Referring now to FIG. 1, a system 100 for classifying Boundary Representation (B-Rep)-based Computer Aided Design (CAD) models is illustrated, in accordance with some embodiments of the present disclosure. The system 100 may automatically classify the B-Rep-based CAD Models as a sheet metal model or a non-sheet metal model. The classification may be used to categorize the B-Rep-based CAD models based on their manufacturing processes, and may help in automating the model lifecycle. Additionally, in some embodiments, the system 100 may also perform a secondary classification for identifying models representing tap information associated with sheet metal models.

To classify the B-Rep-based CAD models, the system 100 includes a classification device 102. Further, in some embodiments, the classification device 102 may include an information extraction module 104, a model type determination module 108, a validation module 110, an analyzer 112, and a labelling module 114. Further, the classification device 102 may also include a data store 116 in order to store intermediate results generated by the modules 104, and 108-114.

The information extraction module 104 may be configured to extract information corresponding to an input B-Rep-based CAD model (for example, the B-Rep model 106). It should be noted that the B-Rep-based CAD model (i.e., the B-Rep model) may include a set of faces. Also, it should be noted that the information may include a plurality of features associated with the B-Rep-based CAD model (the B-Rep model). Further, the information extraction module 104 may be communicatively coupled to the model type determination module 108 and the data store 116.

The model type determination module 108 may be configured to determine a model type associated with the B-Rep-based CAD model (the B-Rep model). The model type may be determined from a set of model types and based on the information. The set of model types may include valid model types and invalid model types. Further, the invalid model types may include a non-manifold body, a multi-part body, a surface body, a wire body, and a free-form region. The model type determination module 108 may be operatively coupled to the validation module 110.

The validation module 110 may be configured to validate the B-Rep-based CAD model (the B-Rep model) when the determined model type is one of the valid model types. It should be noted that, when the model type is one of the surface body or the wire body, the classification device 102 may store information related to such B-Rep model separately (for example, in the data store 116) for further processing, at a later stage while identifying tap bodies. When the model type is one of the valid model types, the B-Rep-based CAD model (i.e., the B-Rep model 106) may be validated based on a set of user input parameters. The set of user input parameters may include a maximum thickness value and a minimum aspect ratio. In some embodiments, the validation module 110 may calculate a thickness of the B-Rep-based CAD model, and an aspect ratio of B-Rep-based CAD model based on the calculated thickness and an area of the reference face. Further, in some embodiments, the validation module 110 may compare the calculated thickness with the maximum thickness value from the set of user input parameters, and the calculated aspect ratio with the minimum aspect ratio from the set of user input parameters. Further, in some embodiments, the validation module 110 may establish the B-Rep-based CAD model (the B-Rep model) as successfully validated when the calculated thickness is less than the maximum thickness value and when the calculated aspect ratio is greater than the minimum aspect ratio.

In some embodiments, the validation module 110 may validate the B-Rep-based CAD model prior to determining the model type. This validation may be performed based on the extracted information. The validation module 110 may be communicatively coupled to the analyzer 112.

The analyzer 112, upon successful validation, may analyze each of the set of faces of the B-Rep-based CAD model (the B-Rep model 106). For analyzation, a reference face may be considered. The reference face may be selected from the set of faces. Further, to select the reference face, the analyzer 112 may include a heuristic model (not shown in FIG. 1). It should be noted that a face type corresponding to each of the set of faces of the B-Rep-based CAD model (the B-Rep model 106) may be identified based on the reference face using the heuristic model. The face type may be selected from a group including a top face, a bottom face, a lateral face, and a miscellaneous face. The analyzer 112 may be communicatively coupled to the labelling module 114 and the data store 116.

In some embodiments, the labelling module 114 may be configured to label the B-Rep-based CAD model (i.e., the B-Rep model 106) as one of a sheet metal body, a non-sheet metal body, or an unclassified body based on the analysis. The sheet metal body may be created by sheet metal operations such as blanking, bending, punching, and the like. Sheet metal models are typically characterized by uniform thickness. The sheet metal models include various elements including walls, bends, form, and stamps. Further, non-sheet metal models may be created by operations other than sheet metal operations. For example, the operations of turning, milling, injection moulding, and the like.

In some embodiments, the B-Rep-based CAD model (the B-Rep model 106) may be labelled as a non-sheet metal body upon completion of non-sheet metal body criteria. The non-sheet metal criteria may include, at least one of determination of the model type as the free-form region, greater calculated thickness than the maximum thickness value, less calculated aspect ratio than the minimum aspect ratio, failed identification of the lateral face, and failed validation of the lateral face.

Further, in some other embodiments, upon completion of unclassified body criteria, the labelling module 114 may be configured to label the B-Rep-based CAD model B-Rep-based CAD model (the B-Rep model 106) as an unclassified body. In an embodiment, the unclassified body criteria may include failed validation of the B-Rep-based CAD model (the B-Rep model 106) based on the extracted information. In an embodiment, the unclassified body criteria may include determination of the model type as one of the non-manifold body or the multi-part body. In an embodiment, the unclassified body criteria may include failed calculation of the thickness. In an embodiment, the unclassified body criteria may include failed determination of the reference face. In an embodiment, the unclassified body criteria may include determination of the model type as one of the surface body or the wire body, and non-association of the B-Rep-based CAD model with a sheet metal body. The surface body includes a single face or a connected set of faces that may not enclose a volume. Further, a wire body includes a single edge or a connected set of edges that may not enclose an area.

The classification device 102 may also include a tap body identification module (not shown in FIG. 1). The tap body identification module may be configured to identify one or more tap bodies in the B-Rep-based CAD model, based on the stored information when the model type is one of the surface body or the wire body, when the B-Rep-based CAD model is labelled as the sheet metal body. The tap body identification module may use a predefined tap criteria for the tap body identification. Tapping in the sheet metal body may represent threads information for connecting one piece of sheet metal to another item. Further, tapping information in the B-Rep CAD model may be represented as a separate body, i.e., a zero-volume body (for example, a surface body) or a zero-area body (for example, a wire body).

It should be noted that the system 100 and associated classification device 102 may be implemented in programmable hardware devices such as programmable gate arrays, programmable array logic, programmable logic devices, or the like. Alternatively, the classification device 100 may be implemented in software for execution by various types of processors. An identified engine/module of executable code may, for instance, include one or more physical or logical blocks of computer instructions which may, for instance, be organized as a component, module, procedure, function, or other construct. Nevertheless, the executables of an identified engine/module need not be physically located together but may include disparate instructions stored in different locations which, when joined logically together, comprise the identified engine/module and achieve the stated purpose of the identified engine/module. Indeed, an engine or a module of executable code may be a single instruction, or many instructions, and may even be distributed over several different code segments, among different applications, and across several memory devices.

As will be appreciated by one skilled in the art, a variety of processes may be employed for classifying Boundary Representation (B-Rep)-based Computer Aided Design (CAD) models. For example, the exemplary system 100 and associated classification device 102 may classify the B-Rep-based CAD model, by the process discussed herein. In particular, as will be appreciated by those of ordinary skill in the art, control logic and/or automated routines for performing the techniques and steps described herein may be implemented by the system 100 and associated classification device 102 either by hardware, software, or combinations of hardware and software. For example, suitable code may be accessed and executed by the one or more processors on the classification device 102 to perform some or all of the techniques described herein. Similarly, application specific integrated circuits (ASICs) configured to perform some or all the processes described herein may be included in the one or more processors on the system 100 and associated classification device 102.

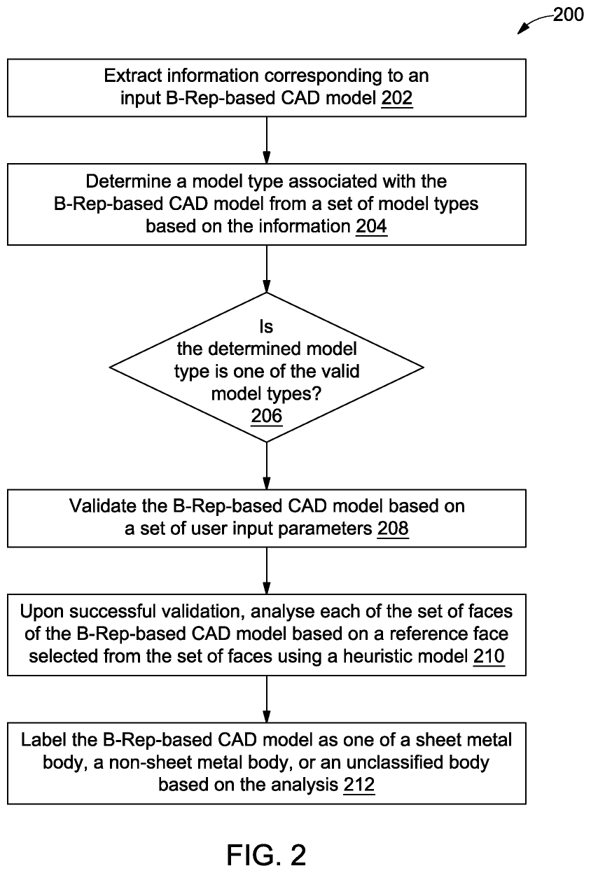

Referring now to FIG. 2, an exemplary process 200 for classifying Boundary Representation (B-Rep)-based Computer Aided Design (CAD) models is depicted via a flow diagram, in accordance with some embodiments of the present disclosure. Each step of the process 200 may be performed by a classification device (similar to the classification device 102). FIG. 2 is explained in conjunction with FIG. 1.

At step 202, information corresponding to an input B-Rep-based CAD model (same as the B-Rep model 106) may be extracted using an information extraction module (similar to the information extraction module 104). The B-Rep-based CAD model may include a set of faces. And, the information may include a plurality of features associated with the B-Rep-based CAD model.

At step 204, a model type associated with the B-Rep-based CAD model may be determined from a set of model types. The model type may be determined using a model type determination module (such as the model type determination module 108). The model type may be determined based on the information. Further, the set of model types may include valid model types and invalid model types. The invalid model types may include a non-manifold body, a multi-part body, a surface body, a wire body, and a free-form region. The surface body and the wire body may be processed further to identify tap bodies. The surface body includes a single face or a connected set of faces that may not enclose a volume, and a wire body includes a single edge or a connected set of edges that may not enclose an area. In some embodiments, a thickness of the B-Rep-based CAD model, and an aspect ratio of B-Rep-based CAD model based on the calculated thickness and an area of the reference face may be calculated. Additionally, in some embodiments, the calculated thickness may be compared with the maximum thickness value from the set of user input parameters. Further, in some embodiments, the calculated aspect ratio may be compared with the minimum aspect ratio from the set of user input parameters. When the calculated thickness is less than the maximum thickness value and when the calculated aspect ratio is greater than the minimum aspect ratio, the B-Rep-based CAD model may be established as successfully validated, in accordance with some embodiments.

Thereafter, at step 206, if the determined model type is one of the valid body types may be checked. In case, the determined model type is one of the valid model types, the B-Rep-based CAD model may be validated, at step 208. It should be noted that the classification device 102 may store this information that the model type is one of the surface body or the wire body separately (for example, in the data store 116) for further processing, in the later stage while identifying tap bodies. For validating the B-Rep-based CAD model, a validation module (such as the validation module 110) may be used. The model type may be validated based on a set of user input parameters. It should be noted that the set of user input parameters may include a maximum thickness value and a minimum aspect ratio. In some embodiments, the B-Rep-based CAD model may be validated on extracted information and prior to determining the model type.

To validate the B-Rep-based CAD model, in some embodiments, a thickness of the B-Rep-based CAD model may be calculated. Further, in some embodiments, an aspect ratio of B-Rep-based CAD model may be calculated based on the calculated thickness and an area of the reference face. Additionally, in some embodiments, the calculated thickness may be compared with the maximum thickness value from the set of user input parameters, and the calculated aspect ratio may be calculated with the minimum aspect ratio from the set of user input parameters. Moreover, in some embodiments, the B-Rep-based CAD model may be established as successfully validated when the calculated thickness is less than the maximum thickness value and when the calculated aspect ratio is greater than the minimum aspect ratio.

Further, at step 210, upon successful validation, each of the set of faces of the B-Rep-based CAD model may be analyzed using an analyser (same as the analyzer 112). A reference face selected from the set of faces may be considered for analyzation. Also, to analyse each set of faces of the B-Rep-based CAD model, a heuristic model may be employed within the analyser, as explained in FIG. 1. In some embodiments, a face type corresponding to each of the set of faces of the B-Rep-based CAD model may be identified based on the reference face using the heuristic model. The face type may be selected from a group of a top face, a bottom face, a lateral face, and a miscellaneous face.

At step 212, the B-Rep-based CAD model may be labelled as one of a sheet metal body, a non-sheet metal body, or an unclassified body based on the analysis, using a labelling module (for example, the labelling module 114). In some embodiments, the B-Rep-based CAD model may be classified as an unclassified body. It should be noted that the B-Rep model may be labelled as the unclassified body, upon completion of unclassified body criteria. The unclassified body criteria may include at least one of failed validation of the B-Rep-based CAD model based on the extracted information, determination of the model type as one of the non-manifold body or the multi-part body, failed calculation of the thickness, failed determination of the reference face, and determination of the model type as one of the surface body or the wire body, and non-association of the B-Rep-based CAD model with a sheet metal body. Further, when the B-Rep-based CAD model is labelled as the sheet metal body, one or more tap bodies in the B-Rep-based CAD model may be identified using the stored information that the model type is one of a surface body or the wire body, based on predefined tap criteria.

Further, in some embodiments, the B-Rep-based CAD model may be labelled as a non-sheet metal body upon completion of non-sheet metal body criteria. The non-sheet metal body criteria may include at least one of determination of the model type as the free-form region, greater calculated thickness than the maximum thickness value, less calculated aspect ratio than the minimum aspect ratio, failed identification of the lateral face, and failed validation of the lateral face.

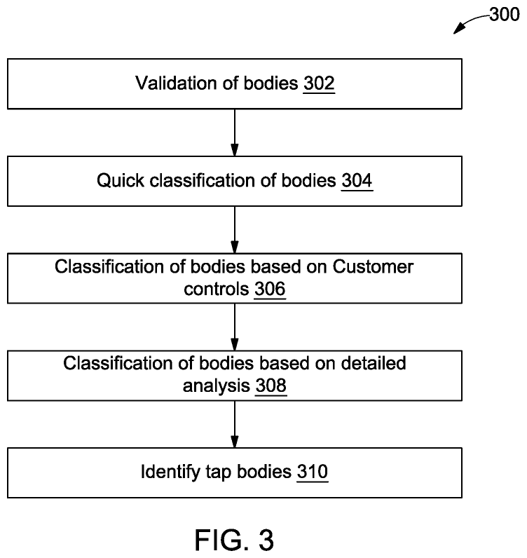

Referring now to FIG. 3, a flow diagram of an exemplary process for identifying tab bodies is depicted via a flowchart, in accordance with some embodiments of the present disclosure. FIG. 3 is explained in conjunction with FIGS. 1-2.

At step 302, a B-Rep model corresponding to each of a plurality of bodies may be validated. Each B-Rep model corresponding to a body may be checked if it defines a valid body or not. It should be noted that standard checks for a B-Rep model corresponding to a body may be applied to check the validity of body data structure. Bodies failing the check are invalid bodies and collected as unclassified bodies. These unclassified bodies may be ignored for further classification.

At step 304, a quick classification for the valid bodies may be performed. The valid bodies may be classified into different categories. The categories may include, but may not be limited to, a non-manifold body type, a multi-part body type, a surface body type, a wire body type, and a free-form region type. A valid body that may not be manufactured by a conventional process falls under a non-manifold body type. Bodies under the category of non-manifold body type are unclassified bodies and are exempted from being processed further for classification. These unclassified bodies are neither sheet metal models nor non-sheet metal models. Standard checks provided by commercially available solid modeling software may be applied to determine the non-manifold body type.

Further, a multi-part body including disconnected volumetric regions may be put into the unclassified bodies and are exempted from being processed further for classification. These bodies are neither sheet metal models nor non-sheet metal models. Detected surface bodies and wire bodies may be stored temporarily and processed last for checking if they represent tap information or not.

Further, free form regions in a body are those regions that have a complex shape and are usually manufactured by sculpting, casting, injection molding or by higher axis material removal machining process. The free form region may be detected and classified as non-sheet metal bodies.

At step 306, classification of the bodies may be performed based on customer controls. A set of control parameters may be received from the user and based on that classification may be performed. The control parameters may include maximum thickness value and minimum aspect ratio value. In some embodiments, an appropriate reference face may be determined automatically based on intelligent heuristics. In case, a reference face for a body is not identified, then the body may be classified as unclassified body and is not processed further for classification. Thereafter, in some embodiments, thickness of the body may be computed. If thickness computation fails, then the body may be put into the unclassified bodies category and ignored for further processing. Based on an internal tolerance defining zero, if the computed thickness value is equal to zero, then the body may get stored temporarily and processed last for checking if it represents tap information.

The thickness value is then compared against the user input maximum thickness value. If the thickness exceeds the value, then the body may get directly classified as a non-sheet metal body. Further, an area of the reference face may be computed, and the aspect ratio may be determined based on the body thickness. This aspect ratio may be compared with the user input minimum aspect ratio value. If the aspect ratio is less than the user input minimum aspect ratio value, the body may be directly classified as a non-sheet metal body.

Thereafter, at step 308, classification of bodies (for example, bodies that pass the user control-based checks) based on detailed analysis may be performed. For detailed analysis-based classification, faces of the body may be segregated into top faces and bottom faces based on the reference face.

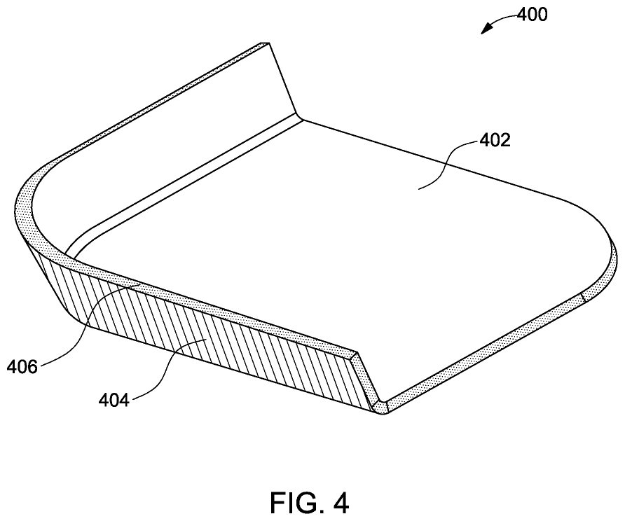

Referring now to FIG. 4, a sheet metal body 400 with segregated faces is illustrated, in accordance with some embodiments of present invention. The sheet metal body 400 includes segregated faces including top faces 402, bottom faces 404, and lateral faces 406.

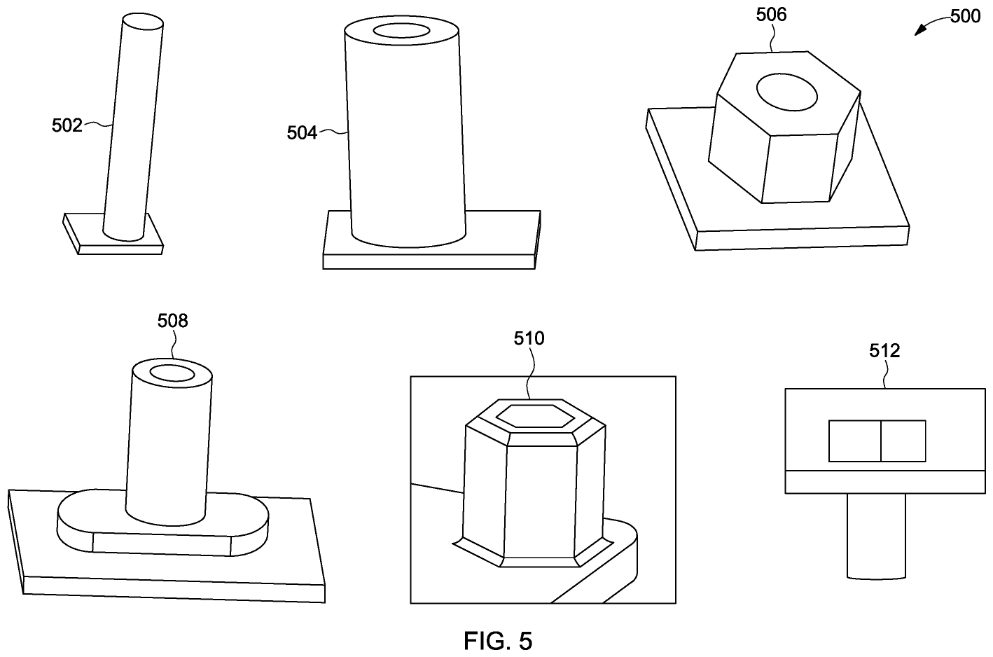

Top faces are collected by propagating through the faces connected with the reference face. Bottom faces are the opposite faces of the collected top faces. Remaining faces of the faces are classified as lateral faces and other faces. The lateral faces correspond to thickness faces of the sheet metal model. It should be noted that the lateral faces are orthogonal to the top faces and the bottom faces. Further, other faces are the ones that are not classified as top faces, bottom faces, or lateral faces. These other faces are still important faces for body classification point of view and are processed further for appropriate segregation into either top faces, bottom faces, lateral face, or Sheet metal faces like a fastener face, a marking face, a half shear face, a chamfer/bevel face, and the like. Some exemplary sheet metal miscellaneous faces are illustrated in FIGS. 5-9.

Referring now to FIG. 5, various exemplary sheet metal fasteners 500 (for example, sheet metal fasteners 502, 504, 506, 508, 510, and 512) are illustrated.

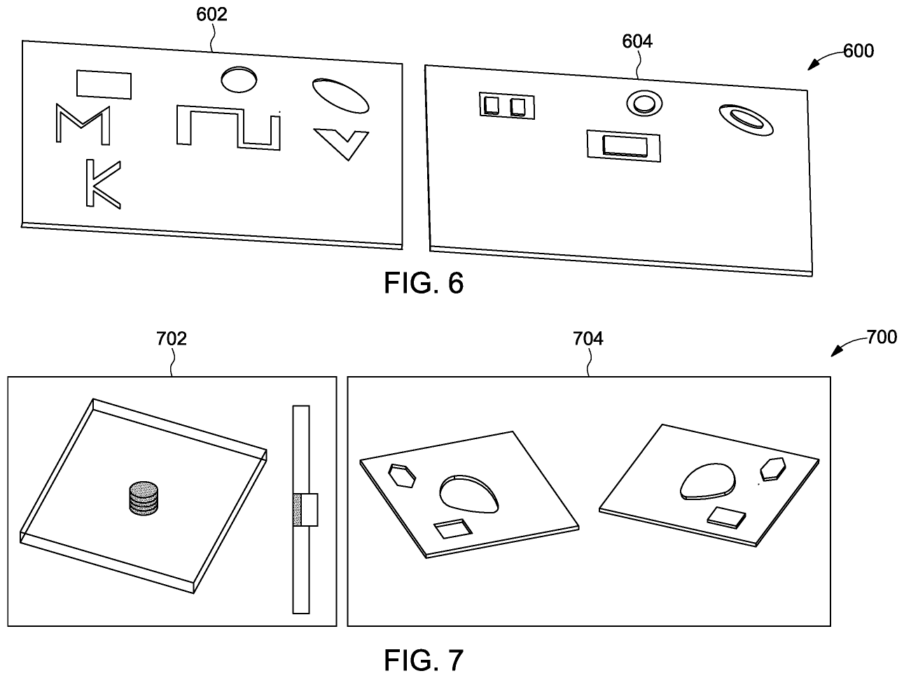

Further, FIG. 6 illustrates exemplary sheet metal markings 600. The sheet metal markings 600 may include round and non-round sheet metal markings 602 and round and no-round sheet metal markings with inner profile 604.

Referring now to FIG. 7, sheet metal half sheers 700 are illustrated, in accordance with some embodiments of the present invention. As illustrated in FIG. 7, the sheet metal half sheers 700 include round half sheer 702 and non-round half sheer 704.

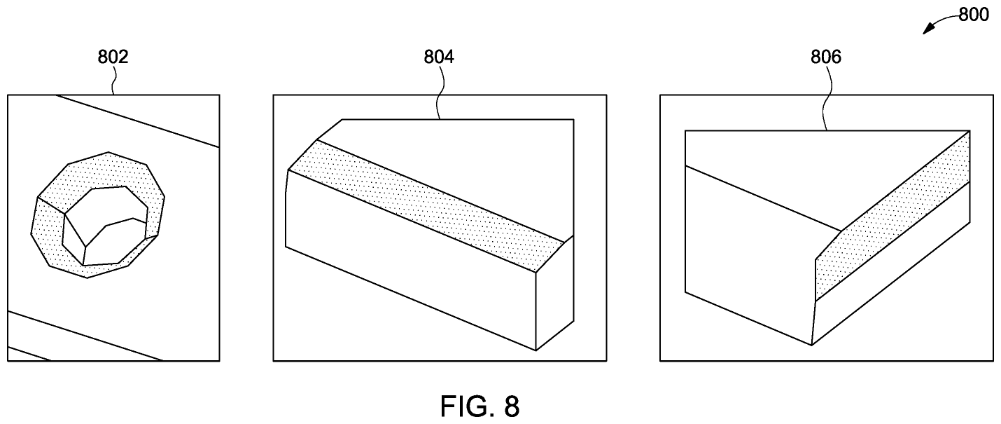

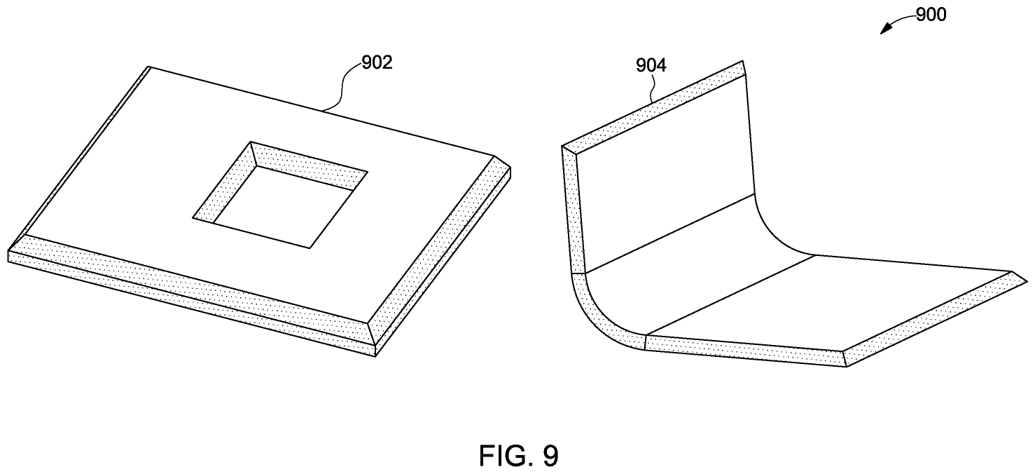

Further, in FIG. 8, exemplary chamfers in sheet metal bodies 800 are illustrated. For example, the sheet metal chamfers are represented by shaded areas 802, 804, 806.

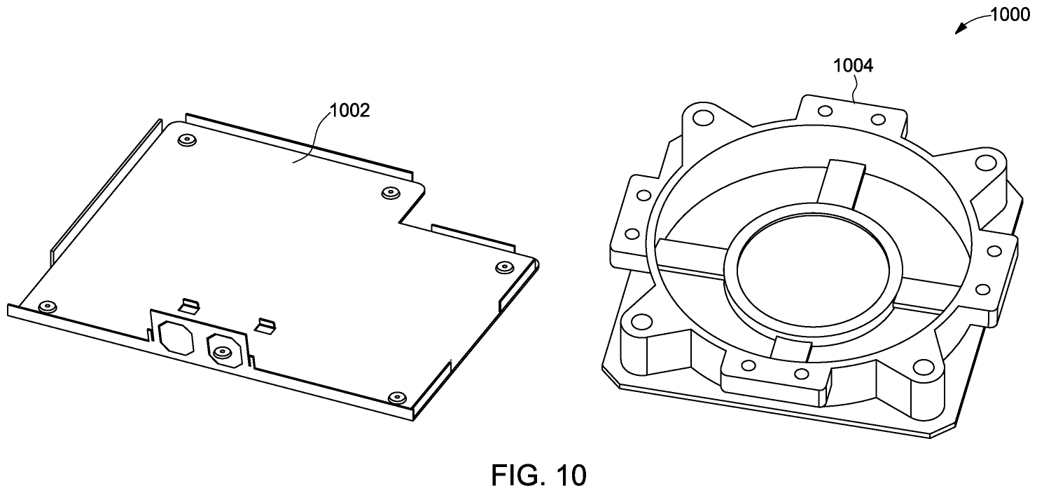

FIG. 9 illustrates exemplary bevels in sheet metal bodies 900. For example, a bevel created on inner and external boundary of wall is represented by shaded portion in a sheet metal body 902. Similarly, a bevel created on external boundary of wall bend is represented by shaded portion in a sheet metal body 904.

The other faces may be processed further for appropriate segregation into either the top faces, the bottom faces, the lateral faces, or the sheet metal faces. It should be noted that intelligent heuristics/clues may be used/identified for the segregation into appropriate face types. Each of the other faces may be first checked for a potential clue of a lateral face. If the potential clue is found then that other face may be categorized as a lateral face (e.g., chamfer/bevel face). Otherwise (If the potential clue is not present), then an immediate neighborhood for that other face may be checked for classifying the other face as a Sheet metal miscellaneous face. Further, if this check also fails, then the other face is finally checked for a top face or a bottom face. In case of failing this check, the body gets classified as a non-sheet metal body.

The lateral faces may be then revalidated again in case they are mistakenly classified as the lateral faces. Finally, if a lateral face revalidation fails, then the body gets classified as the non-sheet metal body.

Referring back to FIG. 3, at step 310, tap bodies may be identified. It should be noted that the surface bodies and the wire bodies temporarily stored during the classification may be processed in this stage. All the surface bodies and the wire bodies are checked for association with the Sheet metal bodies classified in the previous steps. The association may be tested by matching geometry data of the surface body or the wire body with the face/edge data of the Sheet metal body, based on an appropriate association criterion. If any of a surface body or a wire body fails to get associated with a Sheet metal body, then the surface body or the wire body may be classified as an unclassified body.

Referring now to FIG. 10, exemplary Boundary Representation (B-Rep)-based Computer Aided Design (CAD) models 1000 are illustrated, in accordance with some embodiments of the present invention. The B-Rep-based CAD models 1000 may include a B-Rep-based CAD model 1002 and a B-Rep-based CAD model 1004. It should be noted that when the B-Rep-based CAD model 1002 is provided as an input to the classification device 102, the B-Rep-based CAD model 1002 may be classified as a sheet metal body. On the other hand, when the B-Rep-based CAD model 1004 is provided as an input to the classification device 102, the B-Rep-based CAD model 1004 may be classified as a non-sheet metal body.

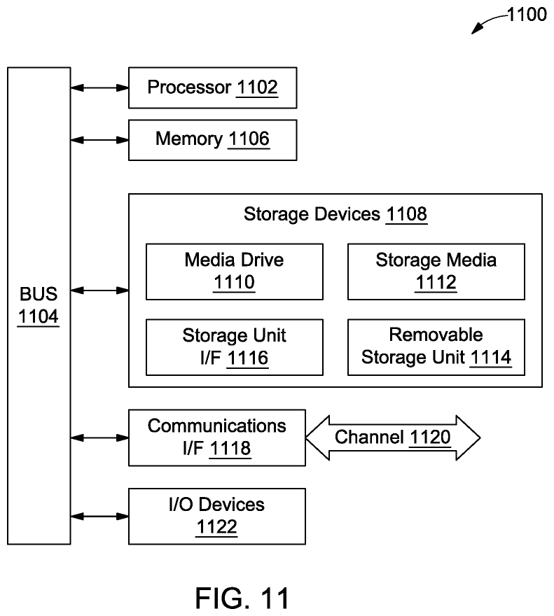

The disclosed methods and systems may be implemented on a conventional or a general-purpose computer system, such as a personal computer (PC) or server computer. Referring now to FIG. 11, an exemplary computing system 1100 that may be employed to implement processing functionality for various embodiments (e.g., as a SIMD device, client device, server device, one or more processors, or the like) is illustrated. Those skilled in the relevant art will also recognize how to implement the invention using other computer systems or architectures. The computing system 1100 may represent, for example, a user device such as a desktop, a laptop, a mobile phone, personal entertainment device, DVR, and so on, or any other type of special or general-purpose computing device as may be desirable or appropriate for a given application or environment. The computing system 1100 may include one or more processors, such as a processor 1102 that may be implemented using a general or special purpose processing engine such as, for example, a microprocessor, microcontroller or other control logic. In this example, the processor 1102 is connected to a bus 1104 or other communication medium. In some embodiments, the processor 1102 may be an AI processor, which may be implemented as a Tensor Processing Unit (TPU), or a graphical processor unit, or a custom programmable solution Field-Programmable Gate Array (FPGA).

The computing system 1100 may also include a memory 1106 (main memory), for example, Random Access Memory (RAM) or other dynamic memory, for storing information and instructions to be executed by the processor 1102. The memory 1106 also may be used for storing temporary variables or other intermediate information during execution of instructions to be executed by the processor 1102. The computing system 1100 may likewise include a read only memory (“ROM”) or other static storage device coupled to bus 1102 for storing static information and instructions for the processor 1102.

The computing system 1100 may also include a storage device 1108, which may include, for example, a media drives 1105 and a removable storage interface. The media drive 1110 may include a drive or other mechanism to support fixed or removable storage media, such as a hard disk drive, a floppy disk drive, a magnetic tape drive, an SD card port, a USB port, a micro USB, an optical disk drive, a CD or DVD drive (R or RW), or other removable or fixed media drive. A storage media 1112 may include, for example, a hard disk, magnetic tape, flash drive, or other fixed or removable medium that is read by and written to by the media drive 1110. As these examples illustrate, the storage media 1112 may include a computer-readable storage medium having stored there in particular computer software or data.

In alternative embodiments, the storage devices 1108 may include other similar instrumentalities for allowing computer programs or other instructions or data to be loaded into the computing system 1100. Such instrumentalities may include, for example, a removable storage unit 1114 and a storage unit interface 1116, such as a program cartridge and cartridge interface, a removable memory (for example, a flash memory or other removable memory module) and memory slot, and other removable storage units and interfaces that allow software and data to be transferred from the removable storage unit 1114 to the computing system 1100.

The computing system 1100 may also include a communications interface 1118. The communications interface 1118 may be used to allow software and data to be transferred between the computing system 1100 and external devices. Examples of the communications interface 1118 may include a network interface (such as an Ethernet or other NIC card), a communications port (such as for example, a USB port, a micro USB port), Near field Communication (NFC), etc. Software and data transferred via the communications interface 1118 are in the form of signals which may be electronic, electromagnetic, optical, or other signals capable of being received by the communications interface 1118. These signals are provided to the communications interface 1118 via a channel 1010. The channel 1120 may carry signals and may be implemented using a wireless medium, wire or cable, fiber optics, or other communications medium. Some examples of the channel 1120 may include a phone line, a cellular phone link, an RF link, a Bluetooth link, a network interface, a local or wide area network, and other communications channels.

The computing system 1100 may further include Input/Output (I/O) devices 1122. Examples may include, but are not limited to a display, keypad, microphone, audio speakers, vibrating motor, LED lights, etc. The I/O devices 1122 may receive input from a user and also display an output of the computation performed by the processor 1102. In this document, the terms “computer program product” and “computer-readable medium” may be used generally to refer to media such as, for example, the memory 1106, the storage devices 1108, the removable storage unit 1114, or signal(s) on the channel 1120. These and other forms of computer-readable media may be involved in providing one or more sequences of one or more instructions to the processor 1102 for execution. Such instructions, generally referred to as “computer program code” (which may be grouped in the form of computer programs or other groupings), when executed, enable the computing system 1100 to perform features or functions of embodiments of the present invention.

In an embodiment where the elements are implemented using software, the software may be stored in a computer-readable medium and loaded into the computing system 1100 using, for example, the removable storage unit 1114, the media drive 1110 or the communications interface 1118. The control logic (in this example, software instructions or computer program code), when executed by the processor 1102, causes the processor 1102 to perform the functions of the invention as described herein.

Thus, the present disclosure may overcome drawbacks of traditional systems discussed before. The present disclosure helps in reducing the uncertainty in classification by considering user controls as per manufacturing environments. Thus, the disclosed method and system in the present disclosure, apart from the classification into sheet metal and non-sheet metal models, the disclosure provides information of unclassified bodies to the user mentioning the reason for failure for the classification, for each unclassified body.

For example, typical thickness of the sheet metal bodies ranges from 0.5 mm thickness to 2 mm thickness. However, if a manufacturer creates sheet metal bodies of 5 mm thickness or more. In that case, the present system may be configured in such a way that the system may classify these bodies as sheet metal bodies, as the user controls are considered.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or process steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A method for classifying Boundary Representation (B-Rep)-based Computer Aided Design (CAD) models, the method comprising:
extracting, by a classification device, information corresponding to an input B-Rep-based CAD model, wherein the B-Rep-based CAD model comprises a set of faces, and wherein the information comprise a plurality of features associated with the B-Rep-based CAD model;
determining, by the classification device, a model type associated with the B-Rep-based CAD model from a set of model types based on the information, wherein the set of model types comprises valid model types and invalid model types, wherein the invalid model types comprise a non-manifold body, a multi-part body, a surface body, a wire body, and a free-form region, and wherein the surface body and the wire body are processed further to identify tap bodies; and
when the determined model type is one of the valid model types:
validating, by the classification device, the B-Rep-based CAD model based on a set of user input parameters, wherein the set of user input parameters comprises a maximum thickness value and a minimum aspect ratio;
upon successful validation, analysing, by the classification device, each of the set of faces of the B-Rep-based CAD model based on a reference face selected from the set of faces using a heuristic model; and
labelling, by the classification device, the B-Rep-based CAD model as one of a sheet metal body, a non-sheet metal body, or an unclassified body based on the analysis.

2. The method of claim 1, further comprising validating the B-Rep-based CAD model based on the extracted information prior to determining the model type.

3. The method of claim 2, wherein validating the B-Rep-based CAD model based on a set of user input parameters comprises:
calculating a thickness of the B-Rep-based CAD model;
calculating an aspect ratio of B-Rep-based CAD model based on the calculated thickness and an area of the reference face;
comparing:
the calculated thickness with the maximum thickness value from the set of user input parameters; and
the calculated aspect ratio with the minimum aspect ratio from the set of user input parameters; and
establishing the B-Rep-based CAD model as successfully validated when the calculated thickness is less than the maximum thickness value and when the calculated aspect ratio is greater than the minimum aspect ratio.

4. The method of claim 3, wherein analysing each of the set of faces of the B-Rep-based CAD model comprises identifying a face type corresponding to each of the set of faces of the B-Rep-based CAD model based on the reference face using the heuristic model, wherein the face type is selected from a group comprising a top face, a bottom face, a lateral face, and a miscellaneous face.

5. The method of claim 4, further comprising labelling the B-Rep-based CAD model as an unclassified body, upon completion of unclassified body criteria, wherein the unclassified body criteria comprise, at least one of:
failed validation of the B-Rep-based CAD model based on the extracted information;
determination of the model type as one of the non-manifold body or the multi-part body;
failed calculation of the thickness;
failed determination of the reference face; and
determination of the model type as one of the surface body or the wire body, and non-association of the B-Rep-based CAD model with a sheet metal body.

6. The method of claim 4, further comprising labelling the B-Rep-based CAD model as a non-sheet metal body upon completion of non-sheet metal body criteria, wherein the non-sheet metal body criteria comprise, at least one of:
determination of the model type as the free-form region;
greater calculated thickness than the maximum thickness value;
less calculated aspect ratio than the minimum aspect ratio;
failed identification of the lateral face; and
failed validation of the lateral face.

7. The method of claim 1, further comprising identifying one or more tap bodies from the surface body and the wire body, using the B-Rep-based CAD model when the B-Rep-based CAD model is labelled as the sheet metal body, using the information based on predefined tap criteria.

8. A system for classifying Boundary Representation (B-Rep)-based Computer Aided Design (CAD) models, the system comprising:
a processor; and
a memory communicatively coupled to the processor, wherein the memory stores processor-executable instructions, which, on execution, cause the processor to:
extract information corresponding to an input B-Rep-based CAD model, wherein the B-Rep-based CAD model comprises a set of faces, and wherein the information comprise a plurality of features associated with the B-Rep-based CAD model;
determine a model type associated with the B-Rep-based CAD model from a set of model types based on the information, wherein the set of model types comprises valid model types and invalid model types, wherein the invalid model types comprise a non-manifold body, a multi-part body, a surface body, a wire body, and a free-form region, and wherein the surface body and the wire body are processed further to identify tap bodies; and
when the determined model type is one of the valid model types:
validate the B-Rep-based CAD model based on a set of user input parameters, wherein the set of user input parameters comprises a maximum thickness value and a minimum aspect ratio;
upon successful validation, analyse each of the set of faces of the B-Rep-based CAD model based on a reference face selected from the set of faces using a heuristic model; and
label the B-Rep-based CAD model as one of a sheet metal body, a non-sheet metal body, or an unclassified body based on the analysis.

9. The system of claim 8, wherein the processor-executable instructions further cause the processor to validate the B-Rep-based CAD model based on the extracted information prior to determining the model type.

10. The system of claim 9, wherein the processor-executable instructions further cause the processor to validate the B-Rep-based CAD model based on a set of user input parameters by:
calculating a thickness of the B-Rep-based CAD model;
calculating an aspect ratio of B-Rep-based CAD model based on the calculated thickness and an area of the reference face;
comparing:
the calculated thickness with the maximum thickness value from the set of user input parameters; and
the calculated aspect ratio with the minimum aspect ratio from the set of user input parameters; and
establishing the B-Rep-based CAD model as successfully validated when the calculated thickness is less than the maximum thickness value and when the calculated aspect ratio is greater than the minimum aspect ratio.

11. The system of claim 10, wherein the plurality of categories comprises a depression face, a protrusion face, a boss/island face, and a fillet face.

12. The system of claim 11, wherein the processor-executable instructions further cause the processor to analyse each of the set of faces of the B-Rep-based CAD model by identifying a face type corresponding to each of the set of faces of the B-Rep-based CAD model based on the reference face using the heuristic model, wherein the face type is selected from a group comprising a top face, a bottom face, a lateral face, and a miscellaneous face.

13. The system of claim 12, wherein the processor-executable instructions further cause the processor to label the B-Rep-based CAD model as an unclassified body, upon completion of unclassified body criteria, wherein the unclassified body criteria comprise, at least one of:
failed validation of the B-Rep-based CAD model based on the extracted information;
determination of the model type as one of the non-manifold body or the multi-part body;
failed calculation of the thickness;
failed determination of the reference face; and
determination of the model type as one of the surface body or the wire body, and non-association of the B-Rep-based CAD model with a sheet metal body.

14. The system of claim 12, wherein the processor-executable instructions further cause the processor to label the B-Rep-based CAD model as a non-sheet metal body upon completion of non-sheet metal body criteria, wherein the non-sheet metal body criteria comprise, at least one of:
determination of the model type as the free-form region;
greater calculated thickness than the maximum thickness value;
less calculated aspect ratio than the minimum aspect ratio;
failed identification of the lateral face; and
failed validation of the lateral face.

15. The system of claim 8, wherein the processor-executable instructions further cause the processor to identify one or more tap bodies from the surface body and the wire body, using the B-Rep-based CAD model when the B-Rep-based CAD model is labelled as the sheet metal body, using the information based on predefined tap criteria.

16. A non-transitory computer-readable medium storing computer-executable instructions for classifying Boundary Representation (B-Rep)-based Computer Aided Design (CAD) models, the computer-executable instructions configured for:
extracting information corresponding to an input B-Rep-based CAD model, wherein the B-Rep-based CAD model comprises a set of faces, and wherein the information comprise a plurality of features associated with the B-Rep-based CAD model;
determining a model type associated with the B-Rep-based CAD model from a set of model types based on the information, wherein the set of model types comprises valid model types and invalid model types, wherein the invalid model types comprise a non-manifold body, a multi-part body, a surface body, a wire body, and a free-form region, and wherein the surface body and the wire body are processed further to identify tap bodies; and
when the determined model type is one of the valid model types:
validating the B-Rep-based CAD model based on a set of user input parameters, wherein the set of user input parameters comprises a maximum thickness value and a minimum aspect ratio;
upon successful validation, analysing each of the set of faces of the B-Rep-based CAD model based on a reference face selected from the set of faces using a heuristic model; and
labelling the B-Rep-based CAD model as one of a sheet metal body, a non-sheet metal body, or an unclassified body based on the analysis.

17. The non-transitory computer-readable medium of the claim 16, wherein the computer-executable instructions further configured for validating the B-Rep-based CAD model based on the extracted information prior to determining the model type.

18. The non-transitory computer-readable medium of the claim 17, wherein the computer-executable instructions further configured for validating the B-Rep-based CAD model based on a set of user input parameters by:
calculating a thickness of the B-Rep-based CAD model;
calculating an aspect ratio of B-Rep-based CAD model based on the calculated thickness and an area of the reference face;
comparing:
the calculated thickness with the maximum thickness value from the set of user input parameters; and
the calculated aspect ratio with the minimum aspect ratio from the set of user input parameters; and
establishing the B-Rep-based CAD model as successfully validated when the calculated thickness is less than the maximum thickness value and when the calculated aspect ratio is greater than the minimum aspect ratio.

19. The non-transitory computer-readable medium of the claim 18, wherein the computer-executable instructions further configured for analysing each of the set of faces of the B-Rep-based CAD model comprises identifying a face type corresponding to each of the set of faces of the B-Rep-based CAD model based on the reference face using the heuristic model, wherein the face type is selected from a group comprising a top face, a bottom face, a lateral face, and a miscellaneous face.

20. The non-transitory computer-readable medium of the claim 19, wherein the computer-executable instructions further configured for labelling the B-Rep-based CAD model as an unclassified body, upon completion of unclassified body criteria, wherein the unclassified body criteria comprise, at least one of:
failed validation of the B-Rep-based CAD model based on the extracted information;
determination of the model type as one of the non-manifold body or the multi-part body;
failed calculation of the thickness;
failed determination of the reference face; and
determination of the model type as one of the surface body or the wire body, and non-association of the B-Rep-based CAD model with a sheet metal body.
